(19) United States
(12) Patent Application Publication
(10) Pub. No.: US 2025/0080054 A1
(43) Pub. Date: Mar. 6, 2025

(54) BIAS CIRCUIT

(71) Applicant: Murata Manufacturing Co., Ltd., Kyoto (JP)

(72) Inventor: Shohei IMAI, Kyoto (JP)

(21) Appl. No.: 18/952,195

(22) Filed: Nov. 19, 2024

Related U.S. Application Data
(63) Continuation of application No. PCT/JP2023/020529, filed on Jun. 1, 2023.

(30) Foreign Application Priority Data
Jun. 3, 2022 (JP) 2022-090651

(51) Int. Cl. H03F 1/02; H03F 3/24

(52) U.S. Cl. CPC H03F 1/0288; H03F 1/0216; H03F 3/245; H03F 2200/451

(57) ABSTRACT

A bias circuit includes: a first transistor having an emitter or source from which a bias is supplied to a first amplifier; a first terminal electrically connected to a circuit that controls a bias of a predetermined amplifier; and a first inverting amplifier having a first input terminal electrically connected to the emitter or source of the first transistor and a first output terminal electrically connected to a base or gate of the first transistor and the first terminal, the first inverting amplifier inverting and amplifying a voltage supplied to the first input terminal.

### CROSS REFERENCE TO RELATED APPLICATION

This is a continuation of International Application No. PCT/JP2023/020529 filed on Jun. 1, 2023 which claims priority from Japanese Patent Application No. 2022-090651 filed on Jun. 3, 2022. The contents of these applications are incorporated herein by reference in their entireties.

### BACKGROUND ART

### Technical Field

The present disclosure relates to bias circuits.

In a Doherty amplifier circuit, in general, a carrier amplifier that operates irrespective of the power level of an input signal and a peak amplifier that becomes OFF when the power level of the input signal is low and becomes ON when the power level is high are connected in parallel. When the power level of the input signal is high, the Doherty amplifier circuit operates as the carrier amplifier maintains saturation at the saturation output power level. That is, in the Doherty amplifier circuit, the peak amplifier is operated at a timing when the carrier amplifier approaches saturation. With this, the Doherty amplifier circuit can improve efficiency compared with a normal power amplifier circuit. Thus, in the power amplifier circuit such as the Doherty amplifier circuit, a circuit that detects saturation of a power amplifier circuit is provided to improve efficiency.
Patent Document 1: U.S. Patent Application Publication No. 2021/36661

### BRIEF SUMMARY

In Patent Document 1, a power amplifier circuit including a saturation detection circuit that detects saturation of a power amplifier is disclosed. In the saturation detection circuit described in Patent Document 1, the input terminal of a saturation detector that detects saturation of the power amplifier is electrically connected to the base of the power amplifier. The saturation detection circuit described in Patent Document 1 detects saturation of the power amplifier by using a voltage drop of the base terminal due to an increase in base current when the power amplifier is saturated. That is, in the saturation detection circuit, it is required to cause a voltage drop at the base terminal of the power amplifier to detect saturation of the power amplifier. Therefore, the saturation detection circuit changes a bias point of the power amplifier due to the voltage drop. Thus, in the power amplifier circuit described in Patent Document 1, a problem arises in which a stable bias cannot be supplied to the power amplifier.

The present disclosure provides a bias circuit for supplying a stable bias to a power amplifier.

A bias circuit according to an aspect of the present disclosure includes: a first transistor having an emitter or source from which a bias is supplied to a first amplifier; a first terminal electrically connected to a circuit that controls a bias of a predetermined amplifier; and a first inverting amplifier having a first input terminal electrically connected to the emitter or source of the first transistor and a first output terminal electrically connected to a base or gate of the first transistor and the first terminal, the first inverting amplifier inverting and amplifying a voltage supplied to the first input terminal.

A bias circuit according to another aspect of the present disclosure includes: a control terminal to which a reference signal for controlling a bias of a first amplifier is inputted; a first transistor having a base or gate electrically connected to the control terminal and an emitter or source from which the bias is supplied to the first amplifier; a second transistor having a collector or drain and a base or gate electrically connected and the collector or drain electrically connected to the emitter or source of the first transistor; a third transistor having a base or gate electrically connected to the control terminal and the base or gate of the first transistor; and an inverting amplifier having a collector or drain electrically connected to an emitter or source of the third transistor and a base or gate electrically connected to the base or gate of the second transistor, the inverting amplifier inverting and amplifying a voltage supplied to the base or gate.

According to the present disclosure, a bias circuit for supplying a stable bias to a power amplifier can be provided.

### BRIEF DESCRIPTION OF THE DRAWINGS

FIG. 1 is a diagram depicting one example of the structure of a power amplifying module of a first embodiment.

FIG. 2 is a diagram depicting one example of the structure of a carrier bias circuit.

FIG. 3 is a diagram depicting one example of a power amplifying module according to a first modification.

FIG. 4 is a diagram depicting one example of a power amplifying module according to a second modification.

FIG. 5 is a diagram depicting one example of a power amplifying module according to a third modification.

FIG. 6 is a diagram depicting one example of a power amplifying module according to a fourth modification.

FIG. 7 is a diagram depicting one example of a power amplifying module according to a fifth modification.

FIGS. 8A and 8B are diagrams depicting the structure of a peak bias circuit of the power amplifying module according to the fifth modification, in which FIG. 8A is a diagram depicting one example of the structure of a peak bias circuit according to a first example and FIG. 8B is a diagram depicting one example of the structure of a peak bias circuit according to a second example.

FIG. 9 is a diagram depicting one example of the structure of a carrier bias circuit of a power amplifying module according to a second embodiment.

FIG. 10 is a diagram depicting one example of the structure of a carrier bias circuit of a power amplifying module according to a third embodiment.

FIG. 11 is a diagram depicting one example of the structure of a carrier bias circuit of a power amplifying module according to a fourth embodiment.

FIG. 12 is a diagram depicting one example of the structure of a carrier bias circuit of a power amplifying module according to a fifth embodiment.

FIG. 13 is a diagram depicting one example of the structure of a peak bias circuit of a power amplifying module according to a modification.

FIG. 14 is a diagram depicting one example of the structure of a carrier bias circuit of a power amplifying module according to a sixth embodiment.

FIG. 15 is a diagram depicting one example of the structure of a carrier bias circuit of a power amplifying module according to a seventh embodiment.

FIG. 16 is a diagram depicting one example of the structure of a carrier bias circuit of a power amplifying module according to an eighth embodiment.

FIG. 17 is a diagram depicting one example of the structure of a carrier bias circuit of a power amplifying module according to a ninth embodiment.

FIG. 18 is a diagram depicting one example of the structure of a peak bias circuit in a power amplifying module according to a modification.

FIG. 19 is a plan view depicting a layout of a carrier bias circuit on a semiconductor substrate in the power amplifying module according to the modification of the fifth embodiment.

### DESCRIPTION OF EMBODIMENTS

Each embodiment of the present disclosure is described below with reference to each drawing. Here, circuit elements with the same reference characters indicate the same circuit element, and redundant description is omitted.

### Structure of Power Amplifying Module 100 According to First Embodiment

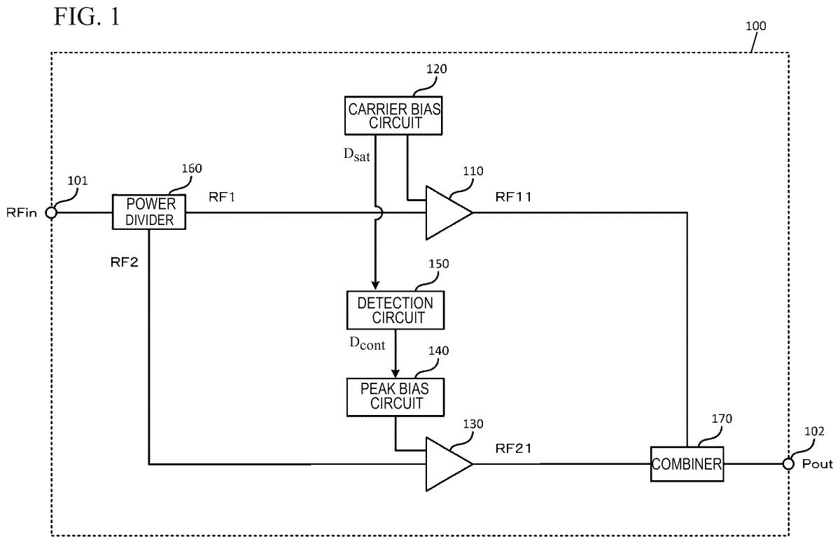

With reference to FIG. 1, the structure of a power amplifying module according to a first embodiment is described. FIG. 1 is a diagram depicting one example of the structure of a power amplifying module 100 of the first embodiment. The power amplifying module 100 is mounted, for example, on a mobile phone, and is used for amplifying power of a signal to be transmitted to a base station. The power amplifying module 100 can amplify power of a signal under communication standards, for example, Second-Generation Mobile Communication System (2G), Third-Generation Mobile Communication System (3G), Fourth-Generation Mobile Communication System (4G), Fifth-Generation Mobile Communication System (5G), LTE (Long Term Evolution)-FDD (Frequency Division Duplex), LTE-TDD (Time Division Duplex), LTE-Advanced, LTE-Advanced Pro, or the like. Note that the communication standards of signals to be amplified by the power amplifying module 100 are not limited to these.

As depicted in FIG. 1, the power amplifying module 100 includes, for example, a carrier amplifier 110, a carrier bias circuit 120, a peak amplifier 130, a peak bias circuit 140, a detection circuit 150, a power divider 160, and a combiner 170. The power amplifying module 100 includes, for example, a Doherty amplifier circuit configured of the carrier amplifier 110 and the peak amplifier 130.

The carrier amplifier 110 is an amplifier that amplifies, for example, a signal RF1 outputted from a power divider 160 and outputs a signal RF11. The carrier amplifier 110 is biased as, for example, Class A, Class AB, or Class B. That is, the carrier amplifier 110 amplifies an input signal and outputs an amplified signal, irrespective of the power level of the input signal such as small instantaneous input power.

The carrier bias circuit 120 is a circuit that supplies a bias to the carrier amplifier 110. The carrier bias circuit 120 has a structure of suppressing a voltage drop occurring due to the bias to be supplied to the carrier amplifier 110. The structure of suppressing a voltage drop in the carrier bias circuit 120 is described further below.

Also, the carrier bias circuit 120 outputs, to the detection circuit 150, for example, a signal (hereinafter referred to as “detection signal Dₛₐₜ”) indicating that the carrier amplifier 110 has been saturated. A structure for outputting the detection signal Dₛₐₜ in the carrier bias circuit 120 is described further below.

The peak amplifier 130 is an amplifier that amplifies, for example, a signal RF2 outputted from the power divider 160 and outputs a signal RF21. The peak amplifier 130 is biased as, for example, Class A, Class AB, Class B, or Class C.

The peak bias circuit 140 is a circuit that supplies a bias to the peak amplifier 130. The peak bias circuit 140 controls a bias to the peak amplifier 130 based on, for example, a control signal D_{cont} outputted from the detection circuit 150 described further below.

The detection circuit 150 is a circuit that detects the detection signal Dₛₐₜ outputted from the carrier bias circuit 120. For example, when detecting the detection signal Dₛₐₜ, the detection circuit 150 outputs a control signal D_{cont} for controlling the bias of the peak bias circuit 140 to the peak bias circuit 140. The peak bias circuit 140 controls the bias based on the control signal D_{cont} so that the peak amplifier 130 operates. With this, the power amplifying module 100 can operate the peak amplifier 130 at an appropriate timing when the carrier amplifier 110 is saturated or starts being saturated.

The power divider 160 divides, for example, a signal RFin into the signal RF1 to be inputted to the carrier amplifier 110 and the signal RF2 to be inputted to the peak amplifier 130. Here, for example, the phase of the signal RF2 is delayed by substantially 90 degrees with respect to the phase of the signal RF1. The power divider 160 may be a distributed constant circuit such as a coupling line 3-dB coupler or a Wilkinson power divider, for example. Note that the term “substantially 90 degrees” includes a range of, for example, 45 degrees to 135 degrees.

A combiner 170 combines, for example, the signal RF11 outputted from the carrier amplifier 110 and passing through a phase shifter (not depicted) and the signal RF21 outputted from the peak amplifier 130 to output an amplified signal Pout.

### <<Structure of Carrier Bias Circuit 120>>

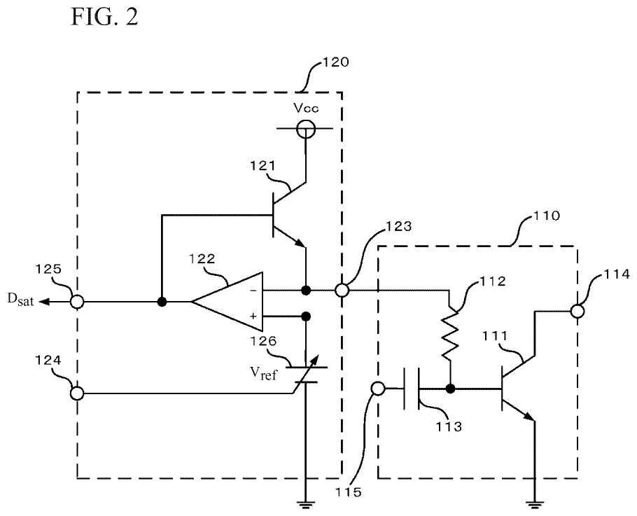

With reference to FIG. 2, one example of the structure of the carrier bias circuit 120 for outputting a detection signal is described. FIG. 2 is a diagram depicting one example of the structure of the carrier bias circuit 120. As depicted in FIG. 2, the carrier bias circuit 120 includes, for example, a transistor 121, an inverting amplifier 122, a bias terminal 123, a control terminal 124, and a detection terminal 125.

Here, the bias terminal 123 is, for example, a terminal for suppling a bias from the carrier bias circuit 120 to the carrier amplifier 110, and is a terminal electrically connected to the base of a transistor 111. Also, the control terminal 124 is, for example, a terminal to which a signal for adjusting a reference voltage 126 is to be inputted. Also, the detection terminal 125 is, for example, a terminal for outputting the detection signal Dₛₐₜ, and is a terminal electrically connected to a circuit that controls a bias of a predetermined amplifier. In the present embodiment, the detection terminal 125 is, for example, electrically connected to the detection circuit 150 that adjusts the bias of the peak amplifier 130.

Note that in FIG. 2, description is made on the assumption that the carrier amplifier 110 includes, for example, the transistor 111, a resistor 112 having one end electrically connected to the bias terminal 123 and the other end electrically connected to the base of the transistor 111, and a capacitor 113 that cuts direct-current components of the signal RF1 inputted through a terminal 115.

The transistor 121 is configured of, for example, a bipolar transistor or a field-effect transistor. In the following, by way of example, description is made on the assumption that the transistor 121 is a bipolar transistor. Note that when the transistor 121 is a field-effect transistor, the base is read as the gate, the collector is read as the drain, and the emitter is read as the source in the following description.

The transistor 121 has its base electrically connected to an output terminal of the inverting amplifier 122, its emitter electrically connected to the bias terminal 123 and an inverting input terminal of the inverting amplifier 122, and its collector electrically connected to a power supply Vcc. To the bias terminal 123, the base of the transistor 111 of the carrier amplifier 110 is electrically connected. That is, the transistor 121 supplies a bias through the bias terminal 123 to the carrier amplifier 110.

The inverting amplifier 122 is configured of, for example, an operational amplifier as a differential amplifier. The inverting amplifier 122 has the inverting input terminal and a non-inverting input terminal, and operates so that a potential difference between the inverting input terminal and the non-inverting input terminal is 0. The output terminal of the inverting amplifier 122 is electrically connected to the detection terminal 125 and the base of the transistor 121. Also, the non-inverting input terminal of the inverting amplifier 122 is electrically connected to the control terminal 124 and is supplied with the reference voltage 126 through the control terminal 124. The inverting input terminal of the inverting amplifier 122 is electrically connected to the emitter of the transistor 121. That is, the inverting amplifier 122 forms a feedback circuit together with the transistor 121. With this, the carrier bias circuit 120 can output a stable bias against a change in output of the transistor 121. Also, the inverting amplifier 122 outputs the detection signal Dₛₐₜ in accordance with the bias supplied from the emitter of the transistor 121, through the detection terminal 125 to the detection circuit 150.

### <<Operation of Carrier Bias Circuit 120>>

Next, the operation of the carrier bias circuit 120 is described with reference to FIG. 1 and FIG. 2. First, the operation of the carrier bias circuit 120 suppressing a voltage drop when supplying a bias is described.

As the input signal RFin depicted in FIG. 1 increases, the signal RF1 inputted from the power divider 160 to the carrier amplifier 110 increases. With the increase of the signal RF1, the emitter current of the transistor 121 of the carrier bias circuit 120 depicted in FIG. 2 increases. In the transistor 121, with the increase of the emitter current, a voltage V_{be} between the base and the emitter increases. That is, as the input signal RFin increases, a voltage drop of the carrier bias circuit 120 increases.

Here, to the inverting input terminal of the inverting amplifier 122, the emitter of the transistor 121 is electrically connected. Also, to the non-inverting input terminal of the inverting amplifier 122, a constant voltage V_{ref} is suppled. That is, in the carrier bias circuit 120, in a state in which the voltage of the non-inverting input terminal is constant, the emitter current of the transistor 121 increases, thereby decreasing the voltage of the inverting input terminal (voltage in accordance with the voltage V_{be}). Here, since a difference between the voltage of the non-inverting input terminal of the inverting amplifier 122 and the voltage of the inverting input terminal increases, the output of the inverting amplifier 122 increases. With this, in the carrier bias circuit 120, the base voltage of the transistor 121 becomes high, and the voltage V_{be} of the transistor 121 can be increased. In this manner, when a voltage drop increases as the input signal RFin increases, the carrier bias circuit 120 provides feedback so that the voltage V_{be} matches the voltage V_{ref} to suppress a voltage drop. With this, the carrier bias circuit 120 can supply a stable bias.

More specifically, for example, when the gain of the inverting amplifier 122 is taken as A, an output voltage V₀ of the carrier bias circuit 120 is indicated by Equation (1). Here, the gain A of the operational amplifier is ideally infinite.

$$\begin{matrix}[ Math . 1 ] & \\ {V}_{O} = \frac{A}{1 + A} {V}_{ref} - \frac{1}{1 + A} {V}_{be} & ( 1 )\end{matrix}$$

As indicated in Equation (1), when the gain A is sufficiently large, the output voltage V₀ of the carrier bias circuit 120 becomes substantially equal to the voltage V_{ref}. That is, in the carrier bias circuit 120, the voltage V_{be} of the transistor 121 does not affect the output voltage V₀ of the carrier bias circuit 120. That is, in the carrier bias circuit 120, fluctuations in voltage can be suppressed even if the emitter current of the transistor 121 increases.

Next, the operation of the carrier bias circuit 120 outputting the detection signal Dₛₐₜ for operating the peak amplifier 130 at an appropriate timing is described.

The inverting amplifier 122 outputs a signal obtained by amplifying a difference between the voltage of the inverting input terminal and the voltage V_{ref} of the non-inverting input terminal. That is, the inverting amplifier 122 can output a signal with an amplified subtle voltage drop due to the emitter current of the transistor 121. With this, as suppressing a voltage drop by the above-described operation of the inverting amplifier 122, the carrier bias circuit 120 can output, from the detection terminal 125, the detection signal Dₛₐₜ indicating a saturated state of the carrier amplifier 110, whereas saturation of the amplifier is detected by intentionally causing a voltage drop in the resistor 27 in the circuit described in Patent Document 1.

Specifically, a voltage V_{d1} of the detection signal Dₛₐₜ is indicated by Equation (2). Here, in the operational amplifier, the gain A is ideally infinite.

$$\begin{matrix}[ Math . 2 ] & \\ {V}_{dl} = \frac{A}{1 + A} ( {V}_{ref} - {V}_{be} ) & ( 2 )\end{matrix}$$

As indicated in Equation (2), when the gain A is sufficiently large, the voltage V_{d1} becomes substantially equal to a difference between the voltage V_{ref} and the voltage V_{be}. That is, in the carrier bias circuit 120, the voltage level of the detection signal Dₛₐₜ can be increased.

From above, in the carrier bias circuit 120, while suppressing a voltage drop with the increase in the emitter current of the transistor 121, it is possible to increase the voltage level of the detection signal Dₛₐₜ.

### First Modification

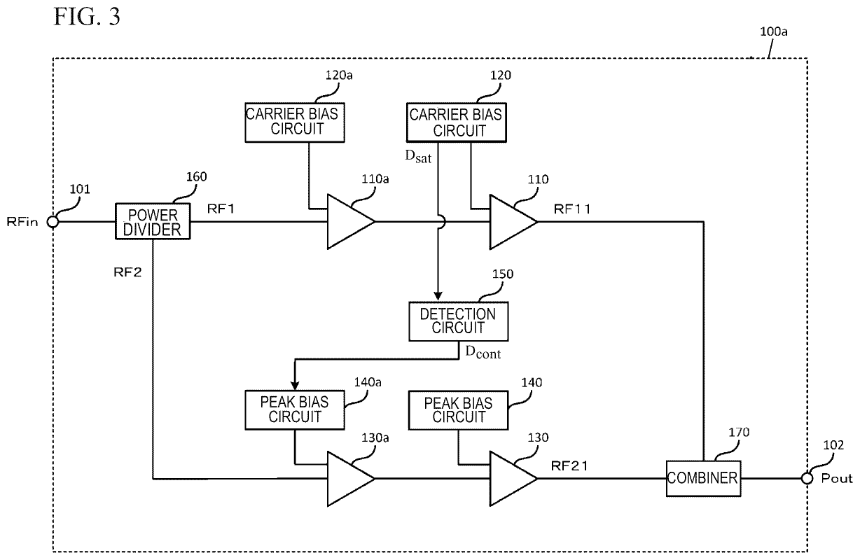

With reference to FIG. 3, a first modification of the power amplifying module 100 is described. FIG. 3 is a diagram depicting one example of a power amplifying module 100a according to the first modification. As depicted in FIG. 3, in the power amplifying module 100a according to the first modification, compared with the power amplifying module 100, the detection circuit 150 controls a drive-stage peak amplifier 130a. Specifically, the power amplifying module 100a includes, for example, a plurality of carrier amplifiers 110 and 110a electrically connected in series and a plurality of peak amplifiers 130 and 130a electrically connected in series. Specifically, the power amplifying module 100a includes the drive-stage carrier amplifier 110a that amplifies the signal RF1 outputted from the power divider 160 and outputs the amplified signal RF1 and the output-stage carrier amplifier 110 that further amplifies the amplified signal RF1 outputted from the drive-stage carrier amplifier 110a for output. Also, the power amplifying module 100a includes the drive-stage peak amplifier 130a that amplifies the signal RF2 outputted from the power divider 160 and outputs the amplified signal RF2 and the output-stage peak amplifier 130 that further amplifies the amplified signal RF2 outputted from the drive-stage peak amplifier 130a for output. The carrier bias circuit 120 is electrically connected to the output-stage carrier amplifier 110 of the plurality of carrier amplifiers 110 and 110a, and outputs the detection signal Dₛₐₜ to the detection circuit 150. For example, the detection circuit 150 outputs the control signal D_{cont} to a peak bias circuit 140a of the drive-stage peak amplifier 130a of the plurality of peak amplifiers 130 and 130a. The peak bias circuit 140a controls the bias based on the control signal D_{cont} so that the drive-stage peak amplifier 130a operates. With this, the power amplifying module 100a can operate the drive-stage peak amplifier 130a at an appropriate timing when the carrier amplifier 110 is saturated. Note that in the power amplifying module 100a, the detection circuit 150 may output the control signal D_{cont} to the peak bias circuit 140 and the peak bias circuit 140a. With this, it is possible to operate the drive-stage peak amplifier 130a and the output-stage peak amplifier 130 at an appropriate timing when the carrier amplifier 110 is saturated.

### Second Modification

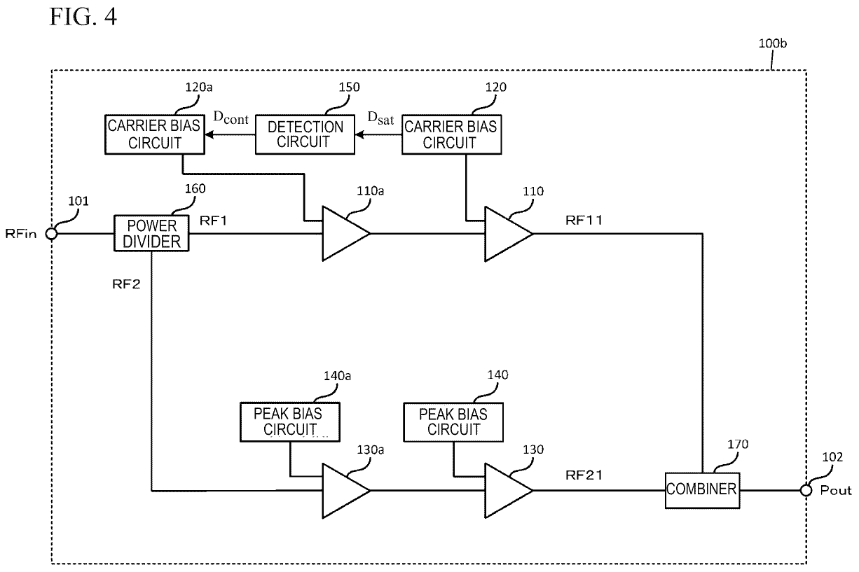

With reference to FIG. 4, a second modification of the power amplifying module 100 is described. FIG. 4 is a diagram depicting one example of a power amplifying module 100b according to the second modification. As depicted in FIG. 4, in the power amplifying module 100b according to the second modification, compared with the power amplifying module 100, the detection circuit 150 controls the drive-stage carrier amplifier 110a. Specifically, the power amplifying module 100b includes, for example, the plurality of carrier amplifiers 110 and 110a and the plurality of peak amplifiers 130 and 130a. The carrier bias circuit 120 is electrically connected to the output-stage carrier amplifier 110, and outputs the detection signal Dₛₐₜ to the detection circuit 150. For example, the detection circuit 150 outputs the control signal D_{cont} to a carrier bias circuit 120a of the drive-stage carrier amplifier 110a. The carrier bias circuit 120a controls the bias to be supplied from the drive-stage carrier bias circuit 120a to the carrier amplifier 110a, based on the control signal D_{cont}. With this, the power amplifying module 100b can adjust the output of the drive-stage carrier amplifier 110a at an appropriate timing when the carrier amplifier 110 is saturated and can suppress distortion of the output of the output-stage carrier amplifier 110.

### Third Modification

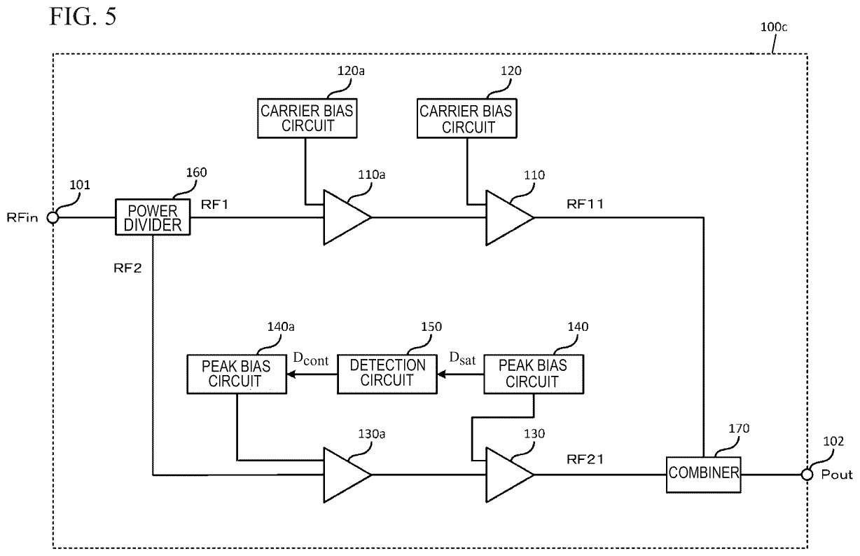

With reference to FIG. 5, a third modification of the power amplifying module 100 is described. FIG. 5 is a diagram depicting one example of a power amplifying module 100c according to the third modification. As depicted in FIG. 5, in the power amplifying module 100c according to the third modification, compared with the power amplifying module 100, the detection circuit 150 acquires the detection signal Dₛₐₜ from the output-stage peak bias circuit 140, and outputs the control signal D_{cont} to the drive-stage peak bias circuit 140. Specifically, the power amplifying module 100c includes, for example, the plurality of carrier amplifiers 110 and 110a and the plurality of peak amplifiers 130 and 130a. The peak bias circuit 140 is electrically connected to the output-stage peak amplifier 130, and outputs the detection signal Dₛₐₜ to the detection circuit 150. For example, the detection circuit 150 outputs the control signal D_{cont} to the peak bias circuit 140a of the drive-stage peak amplifier 130a. The peak bias circuit 140a controls the bias to be supplied from the drive-stage peak bias circuit 140a to the peak amplifier 130a, based on the control signal D_{cont}. With this, the power amplifying module 100c can adjust the output of the drive-stage peak amplifier 130a in accordance with the output level of the peak amplifier 130 and can suppress distortion of the output of the output-stage peak amplifier 130.

### Fourth Modification

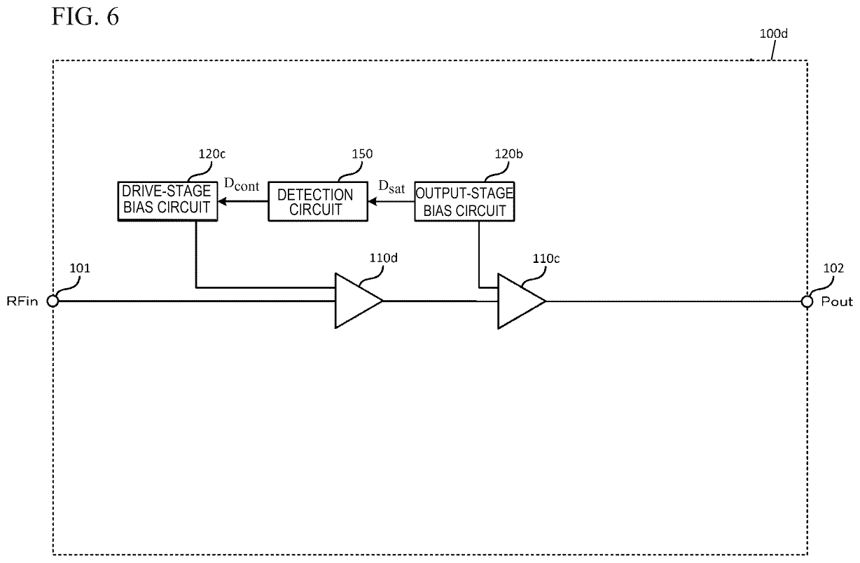

With reference to FIG. 6, a fourth modification of the power amplifying module 100 is described. FIG. 6 is a diagram depicting one example of a power amplifying module 100d according to the fourth modification. As depicted in FIG. 6, in the power amplifying module 100d according to the fourth modification, compared with the power amplifying module 100, no Doherty circuit is formed, and a plurality of amplifiers are electrically connected in series. In the power amplifying module 100d, the detection circuit 150 controls a drive-stage amplifier 110d.

Here, an output-stage bias circuit 120b is assumed to have the same structure as that of the carrier bias circuit 120. The power amplifying module 100d includes, for example, a drive-stage amplifier 110d and an output-stage amplifier 110c. An output-stage bias circuit 120b is electrically connected to the output-stage amplifier 110c, and outputs the detection signal Dₛₐₜ to the detection circuit 150. For example, the detection circuit 150 outputs the control signal D_{cont} to a drive-stage bias circuit 120c of the drive-stage amplifier 110d. The drive-stage bias circuit 120c controls the bias to be supplied from the drive-stage bias circuit 120c to the drive-stage amplifier 110d, based on the control signal D_{cont}. With this, the power amplifying module 100d can adjust the output of the drive-stage amplifier 110d in accordance with the output level of the output-stage amplifier 110c, and thus can suppress distortion of the output of the output-stage amplifier 110c.

### Fifth Modification

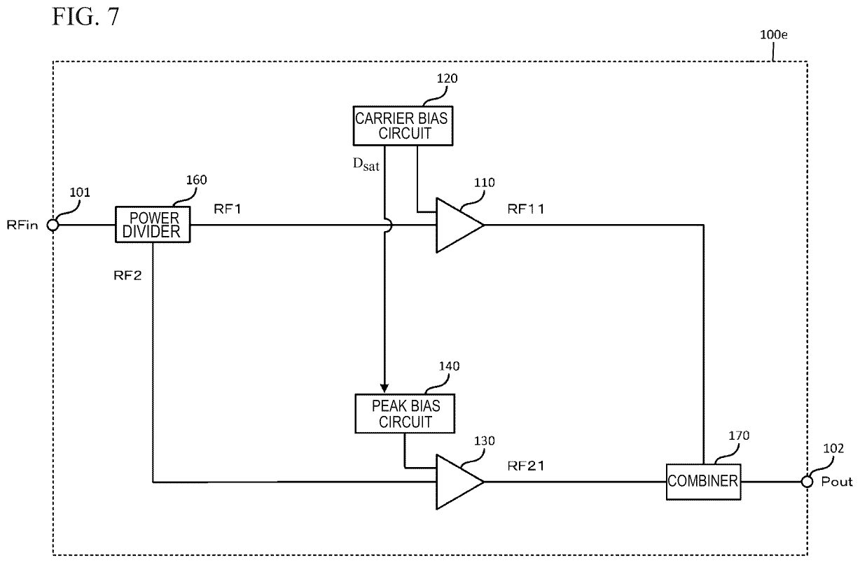

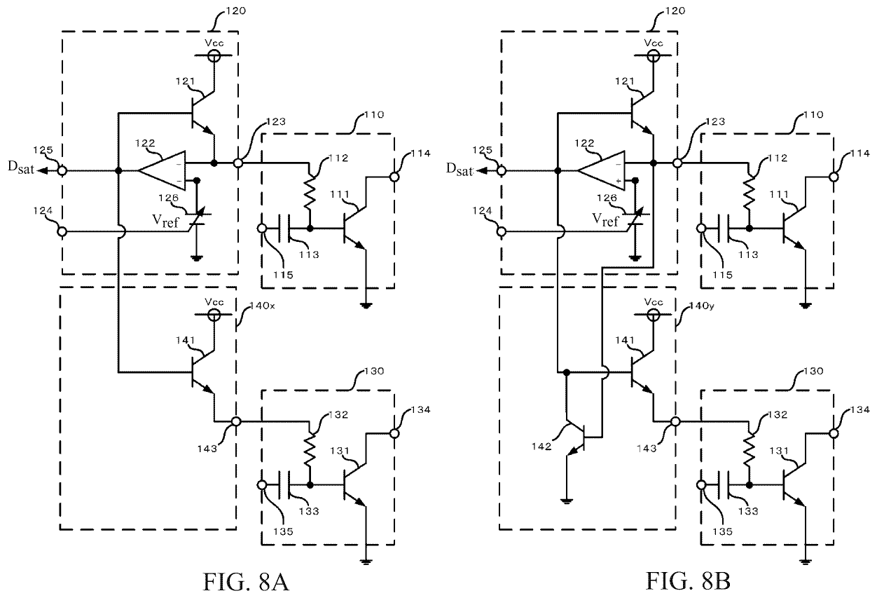

With reference to FIG. 7 and FIGS. 8A and 8B, a fifth modification of the power amplifying module 100 is described. FIG. 7 is a diagram depicting one example of a power amplifying module 100e according to the fifth modification. As depicted in FIG. 7, in the power amplifying module 100e according to the fifth modification, compared with the power amplifying module 100, the detection signal Dₛₐₜ is directly inputted from the carrier bias circuit 120 to the peak bias circuit 140 to adjust the output of the peak amplifier 130. In the power amplifying module 100e, the peak bias circuit 140 controls the bias to be supplied to the peak amplifier 130, based on the detection signal Dₛₐₜ.

With reference to FIG. 8A and FIG. 8B, details of the structure of the peak bias circuit 140 that controls the bias of the peak amplifier 130 based on the detection signal Dₛₐₜ outputted from the carrier bias circuit 120 are described.

FIG. 8A is a diagram depicting the structure of a peak bias circuit 140x according to a first example. The peak bias circuit 140x includes a transistor 141.

The transistor 141 is configured of, for example, a bipolar transistor or a field-effect transistor. In the following, by way of example, description is made on the assumption that the transistor 141 is a bipolar transistor. Note that when the transistor 141 is a field-effect transistor, the base is read as the gate, the collector is read as the drain, and the emitter is read as the source in the following description.

The transistor 141 has its base electrically connected to the detection terminal 125 included in the carrier bias circuit 120 or the output terminal of the inverting amplifier 122, its emitter electrically connected to a bias terminal 143, and its collector electrically connected to a power supply Vcc. To the bias terminal 143, the base of a transistor 131 of the peak amplifier 130 is electrically connected.

That is, the transistor 141 supplies a bias through the bias terminal 143 to the peak amplifier 130.

In the power amplifying module 100e, to the base of the transistor 141 included in the peak bias circuit 140, the detection signal Dₛₐₜ is directly inputted from the detection terminal 125 included in the carrier bias circuit 120. Here, since the transistor 141 operates as an emitter follower, the impedance of the detection signal Dₛₐₜ is supplied to the peak bias circuit 140 in a state of being low compared with a time when the detection signal Dₛₐₜ is outputted from the carrier bias circuit 120. With this, when the carrier amplifier 110 is saturated, the peak amplifier 130 can be automatically operated (without necessarily using the detection circuit 150) at an appropriate timing.

FIG. 8B is a diagram depicting the structure of a peak bias circuit 140y according to a second example. The peak bias circuit 140y includes the transistor 141 and a transistor 142.

The transistor 142 is configured of, for example, a bipolar transistor or a field-effect transistor. In the following, by way of example, description is made on the assumption that the transistor 142 is a bipolar transistor. Note that when the transistor 142 is a field-effect transistor, the base is read as the gate, the collector is read as the drain, and the emitter is read as the source in the following description.

The transistor 142 has its base electrically connected to the emitter of the transistor 121 included in the carrier bias circuit 120, its emitter electrically connected to ground, and its collector electrically connected to the base of the transistor 141. The transistor 142 functions as an emitter-grounded inverting amplifier, and invertedly amplifies the voltage of the emitter of the carrier bias circuit 120 (or the voltage of the inverting input terminal of the inverting amplifier 122) for output to the base of the transistor 141. With this, in the emitter of the transistor 121, even when a voltage drop that cannot be sufficiently suppressed by the carrier bias circuit 120 occurs, the bias can be appropriately supplied to the peak amplifier 130.

Note that while the above description has been made in which the control signal D_{cont} is outputted from the detection circuit 150, this is not meant to be restrictive. For example, the detection signal Dₛₐₜ may be directly inputted from the carrier bias circuit 120 to the peak amplifier 130 to adjust the output of the peak amplifier 130.

### Power Amplifying Module 200 According to Second Embodiment

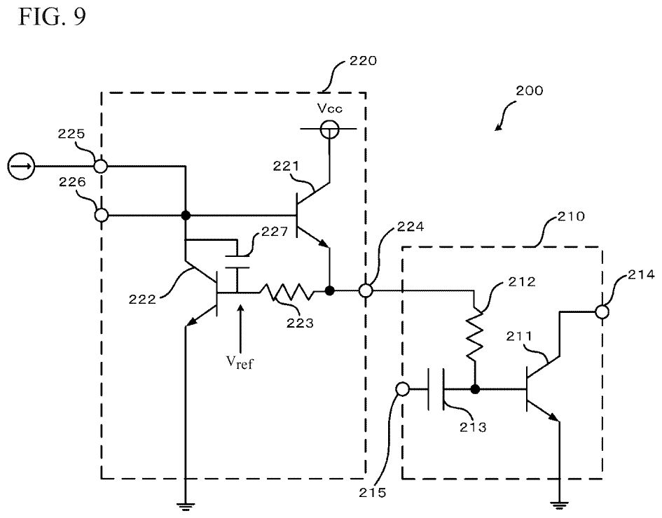

With reference to FIG. 9, the structure of a carrier bias circuit 220 of a power amplifying module 200 according to a second embodiment is described. FIG. 9 is a diagram depicting one example of the structure of the carrier bias circuit 220 of the power amplifying module 200 according to the second embodiment.

As depicted in FIG. 9, compared with the power amplifying module 100, the power amplifying module 200 includes, in place of the inverting amplifier 122 of the carrier bias circuit 120, the carrier bias circuit 220 configured of a transistor (hereinafter, transistor 222) that inverts and amplifies the voltage. Structures different from those of the power amplifying module 100 are described below.

Specifically, as depicted in FIG. 9, the carrier bias circuit 220 includes a transistor 221 and a transistor 222. The base of the transistor 221, is electrically connected to a control terminal 225 to which a reference signal S_{base} as a signal for controlling a bias point of a carrier amplifier 210 is inputted.

The transistor 222 is configured of, for example, a bipolar transistor or a field-effect transistor. In the following, by way of example, description is made on the assumption that the transistor 222 is a bipolar transistor. Note that when the transistor 222 is a field-effect transistor, the base is read as the gate, the collector is read as the drain, and the emitter is read as the source in the following description.

First, the structure of the carrier bias circuit 220 is described. The collector of the transistor 222 is electrically connected to the control terminal 225 and a detection terminal 226. That is, in the carrier bias circuit 220, the control terminal 225 and the detection terminal 226 may be connected to the same node. The base of the transistor 222 is electrically connected to the emitter of the transistor 221 and a bias terminal 224 through a resistor 223. The emitter of the transistor 222 is electrically connected to ground. Note that the base of the transistor 222 is not required to be connected to the emitter of the transistor 221 through the resistor 223 and may be electrically connected directly to the emitter of the transistor 221. With this, the size of the carrier bias circuit 220 can be decreased.

Next, the operation of the carrier bias circuit 220 is described. In the carrier bias circuit 220, most of currents inputted to the control terminal 225 flows to the collector of the transistor 222. Then, through the base of the transistor 221, a current in accordance with the current flowing through the collector of the transistor 222 flows. The current flowing through the base of the transistor 221 causes the voltage V_{be} between the base and the emitter of the transistor 221. With this, the voltage V_{ref} of the transistor 222 depicted in FIG. 9 is determined. Here, when the bias current that the carrier bias circuit 220 supplies to the carrier amplifier 210 increases, the output voltage of the carrier bias circuit 220 decreases by a voltage drop. Here, the current flowing through the base of the transistor 222 decreases. With this, the transistor 222 invertedly amplifies the voltage, thereby causing the collector potential of the transistor 222 to increase and the base potential of the transistor 221 to increase. This causes a feedback mechanism to function in the carrier bias circuit 220 so as to suppress a decrease in output voltage. Also, as described above, since the collector potential of the transistor 222 increases, a large detection signal Dₛₐₜ can be obtained through the detection terminal 226.

That is, in the carrier bias circuit 220, compared with the carrier bias circuit 120, the inverting amplifier 122 and supply of the reference voltage 126 (voltage V_{ref}) is achieved by a single transistor (transistor 222). Thus, the circuit size can be decreased.

Note that the transistor 222 may have its base and collector to be electrically connected through a capacitor 227. With this, it is possible to suppress oscillation that can occur due to positive feedback of part of the emitter current of the transistor 221 as a base current of the transistor 222. Thus, in the carrier bias circuit 220 having the capacitor electrically connecting the base and the collector, the circuit characteristics are stabilized. Also, it is assumed that the carrier bias circuit 220 can be applied in place of the output-stage bias circuit 120b in the power amplifying module 100d according to the fourth modification depicted in FIG. 6.

### Power Amplifying Module 300 According to Third Embodiment

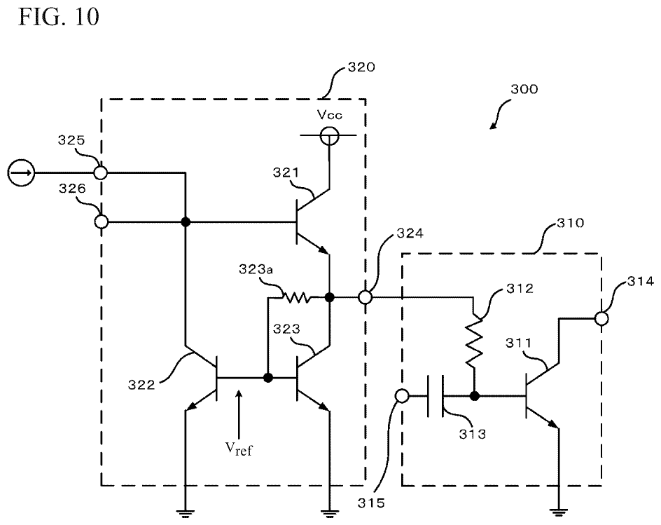

With reference to FIG. 10, the structure of a carrier bias circuit 320 of a power amplifying module 300 according to a third embodiment is described. FIG. 10 is a diagram depicting one example of the structure of the carrier bias circuit 320 of the power amplifying module 300 according to the third embodiment.

As depicted in FIG. 10, compared with the power amplifying module 200, the power amplifying module 300 further includes a transistor 323 diode-connected via a resistor 323a in the carrier bias circuit 320. Components different from those of the power amplifying module 200 are described below.

The carrier bias circuit 320 includes a transistor 321, a transistor 322, and the transistor 323.

The transistor 323 is configured of, for example, a bipolar transistor or a field-effect transistor. In the following, by way of example, description is made on the assumption that the transistor 323 is a bipolar transistor. Note that when the transistor 323 is a field-effect transistor, the base is read as the gate, the collector is read as the drain, and the emitter is read as the source in the following description.

The collector of the transistor 323 is electrically connected to the emitter of the transistor 321. The base of the transistor 323 is electrically connected to the base of the transistor 322. The emitter of the transistor 323 is electrically connected to ground. That is, in the carrier bias circuit 320, the transistor 323 diode-connected to the emitter of the transistor 321 is electrically connected.

Here, the base of the transistor 322 is electrically connected to the base of the transistor 323.

The resistor 323a has one end connected to the base of the transistor 323 and the other end connected to the collector of the transistor 323. That is, the transistor 323 is diode-connected via the resistor 323a.

The operation of the carrier bias circuit 320 is similar to the operation of the carrier bias circuit 220 and is therefore not described. Note that in the carrier bias circuit 320, with the diode-connected transistor 323 connected to the emitter of the transistor 321, the base current of the transistor 322 can be decreased. Specifically, with the diode-connected transistor 323 connected to the emitter of the transistor 321, a current that is approximately several-tens-fold or larger than the base current of the transistor 322 can be consumed at the emitter of the transistor 321. That is, in the second embodiment, it is possible to suppress oscillation that can occur due to positive feedback of part of the emitter current of the transistor 221 as a base current of the transistor 222. Thus, in the carrier bias circuit 320 having the transistor 323, the circuit characteristics are stabilized. Also, in the carrier bias circuit 320, by providing the transistor 323 suppressing oscillation, it is possible to omit the capacitor 227 in the carrier bias circuit 220. Thus, the circuit size can be decreased.

Also, for example, when the base of the transistor 323 is directly connected to a bias terminal 324 electrically connected to the base of a transistor 311 configuring the carrier amplifier 310, an RF signal inputted to the base of the transistor 311 through a terminal 315 is simultaneously inputted also to the base of the transistor 322. Here, since the RF signal flowing into the base of the transistor 322 is consumed at the transistor 322, there is a possibility that power of the RF signal inputted to the base of the transistor 311 is decreased to cause a decrease in gain of the carrier amplifier 310. Moreover, there is also a possibility that the transistor 322 amplifies the RF signal flowing into the base for output from a detection terminal 326 to cause erroneous operation of the carrier bias circuit 320.

By contrast, in the power amplifying module 300, in the carrier bias circuit 320, the transistor 323 diode-connected via the resistor 323a is provided. With this, it is possible to decrease a flow of the RF signal inputted to the carrier amplifier 310 into the base of the transistor 322 and reduce erroneous operation of the carrier bias circuit 320.

Note that it is assumed that the carrier bias circuit 320 can be applied in place of the output-stage bias circuit 120b in the power amplifying module 100d according to the fourth modification depicted in FIG. 6.

### Power Amplifying Module 400 According to Fourth Embodiment

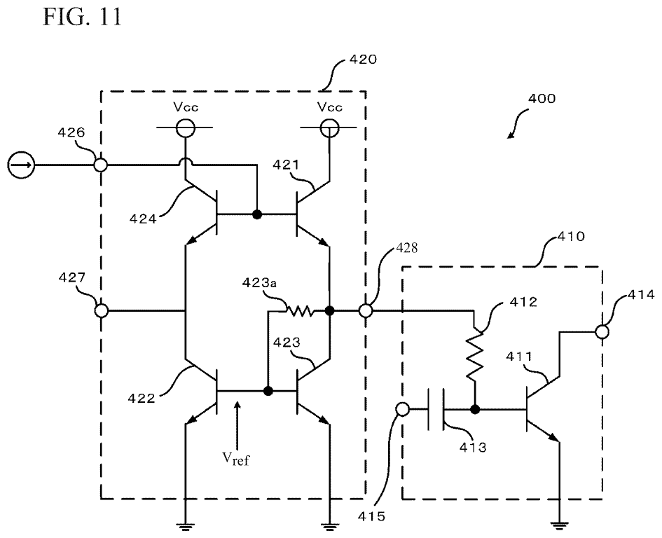

With reference to FIG. 11, the structure of a carrier bias circuit 420 of a power amplifying module 400 according to a fourth embodiment is described. FIG. 11 is a diagram depicting one example of the structure of the carrier bias circuit 420 of the power amplifying module 400 according to the fourth embodiment.

As depicted in FIG. 11, compared with the power amplifying module 300, the power amplifying module 400 further includes a transistor 424 in the carrier bias circuit 420. Components different from those of the power amplifying module 300 are described below.

The carrier bias circuit 420 includes a transistor 421, a transistor 422, a transistor 423, a resistor 423a, and the transistor 424.

The transistor 424 is configured of, for example, a bipolar transistor or a field-effect transistor. In the following, by way of example, description is made on the assumption that the transistor 424 is a bipolar transistor. Note that when the transistor 424 is a field-effect transistor, the base is read as the gate, the collector is read as the drain, and the emitter is read as the source in the following description.

The collector of the transistor 424 is electrically connected to the power supply Vcc. The base of the transistor 424 is electrically connected to a control terminal 426 and the base of the transistor 421. The emitter of the transistor 424 is electrically connected to the collector of the transistor 422.

Note that the collector of the transistor 422 is electrically connected to a detection terminal 427.

The operation of the carrier bias circuit 420 is similar to the operation of the carrier bias circuit 320 and is therefore not described. Note that in the carrier bias circuit 420, in addition to the effects of the carrier bias circuit 320, an effect of a decrease in impedance is exerted because the detection signal Dₛₐₜ is outputted from the emitter of the transistor 424. Therefore, the detection signal Dₛₐₜ outputted from the detection terminal 427 can be more accurately obtained.

### Power Amplifying Module 500 According to Fifth Embodiment

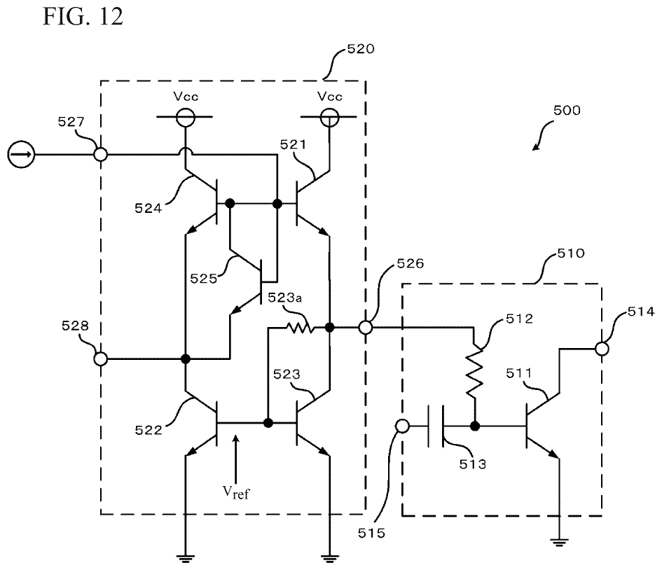

With reference to FIG. 12, the structure of a carrier bias circuit 520 of a power amplifying module 500 according to a fifth embodiment is described. FIG. 12 is a diagram depicting one example of the structure of the carrier bias circuit 520 of the power amplifying module 500 according to the fifth embodiment.

As depicted in FIG. 12, compared with the power amplifying module 400, the power amplifying module 500 further includes a transistor 525 in the carrier bias circuit 520. Components different from those of the power amplifying module 400 are described below.

The carrier bias circuit 520 includes a transistor 521, a transistor 522, a transistor 523, a resistor 523a, a transistor 524, and the transistor 525.

The transistor 525 is configured of, for example, a bipolar transistor or a field-effect transistor. In the following, by way of example, description is made on the assumption that the transistor 525 is a bipolar transistor. Note that when the transistor 525 is a field-effect transistor, the base is read as the gate, the collector is read as the drain, and the emitter is read as the source in the following description.

The transistor 525 is a diode-connected transistor. The collector and base of the transistor 525 are electrically connected to the base of the transistor 524. The emitter of the transistor 525 is electrically connected to the collector of the transistor 522. Note that the collector of the transistor 522 is electrically connected to a detection terminal 528. That is, the transistor 525 has a current-mirror relation with respect to the voltage V_{be} between the base and the emitter of the transistor 524. With this, to the collector of the transistor 524, a current proportional to the current inputted from a control terminal 527 can be let flow.

The operation of the carrier bias circuit 520 is similar to the operation of the carrier bias circuit 420 and is therefore not described. Note that in the carrier bias circuit 520, as described above, since a current proportional to the current inputted from the control terminal 527 can be let flow to the collector of the transistor 524, in addition to the effects of the carrier bias circuit 420 according to the fourth embodiment, an effect can be exerted in which the carrier bias circuit 520 can be configured with an input current with accuracy lower than the accuracy of the current inputted from the control terminal 426 in the carrier bias circuit 420.

Specifically, in the carrier bias circuit 420 according to the fourth embodiment, since the reference voltage V_{ref} is determined with the base currents of the transistor 421 and the transistor 424, which have significantly small current values, high accuracy is required for the current inputted from the control terminal 426. On the other hand, in the carrier bias circuit 520 according to the present embodiment, since the current inputted from the control terminal 527 is supplied also to the collector of the transistor 525, accuracy of the current for determining the reference voltage V_{ref} can be reduced. With this, an effect of stabilizing the operation of the carrier bias circuit 520 is exerted.

### Modification

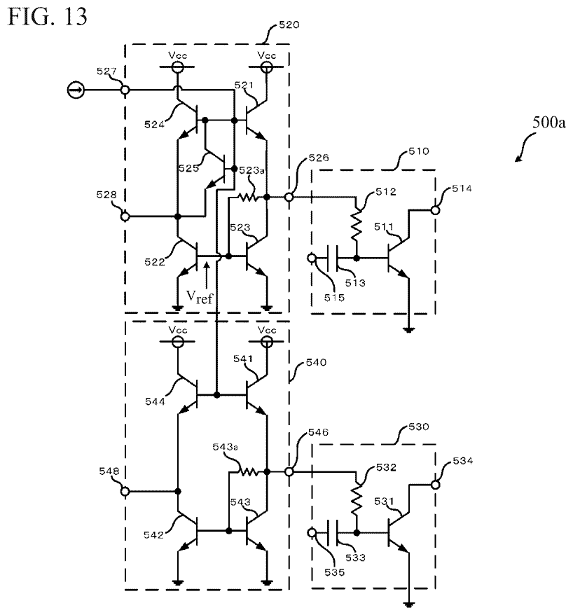

With reference to FIG. 13, a modification of the power amplifying module 500 is described. FIG. 13 is a diagram depicting one example of the structure of a peak bias circuit 540 in a power amplifying module 500a according to the modification. In the power amplifying module 500a according to the modification, as with the power amplifying module 100e, the detection signal Dₛₐₜ is directly inputted from the carrier bias circuit 520 to the peak bias circuit 540 to adjust the output of a peak amplifier 530. In the power amplifying module 500a, the peak bias circuit 540 controls a bias to be supplied to the peak amplifier 530, based on the detection signal Dₛₐₜ.

The peak bias circuit 540 includes a transistor 541, a transistor 542, a transistor 543, a resistor 543a, a transistor 544, and a detection terminal 548. Since the structure of the peak bias circuit 540 is similar to the structure of the carrier bias circuit 420 of the power amplifying module 400 according to the fourth embodiment, components different from those of the carrier bias circuit 420 are described below. Note that the peak bias circuit 540 may have the same structure as that of the carrier bias circuit of each of the power amplifying modules according to the first embodiment, the second embodiment, the third embodiment, and the fifth embodiment.

The peak bias circuit 540 is different from the carrier bias circuit 420 in that the base of the transistor 541 and the base of the transistor 544 are not connected to a control terminal. Instead, in the peak bias circuit 540, the base of the transistor 541 and the base of the transistor 544 are electrically connected to the base of the transistor 524 and the base of the transistor 525 included in the carrier bias circuit 520. That is, in the power amplifying module 500a, the detection signal Dₛₐₜ directly inputted from the carrier bias circuit 520 to the peak bias circuit 540 is not a signal outputted from a detection terminal but a signal outputted from the base of the transistor 524 and the base of the transistor 525.

By outputting the detection signal Dₛₐₜ inputted to the peak bias circuit 540 from the base of the transistor 524 and the base of the transistor 525 included in the carrier bias circuit 520, it is possible to shift the voltage of the detection signal Dₛₐₜ by an amount required for input to the peak bias circuit 540. For example, in the present modification, the voltage of the detection signal Dₛₐₜ is shifted by the voltage (V_{be}) between the base and the emitter of the transistor 525, compared with a case in which the detection signal Dₛₐₜ is outputted from the detection terminal 528 of the carrier bias circuit 520. With this, it is possible to input the detection signal Dₛₐₜ with a more appropriate voltage to the peak amplifier 530.

Note that, here, a signal outputted from the detection terminal 528 of the carrier bias circuit 520 and a signal outputted from the detection terminal 548 of the peak bias circuit 540 can be used for control other than control of the peak bias circuit (for example, control of input power to the power amplifying module 500a itself).

### Power Amplifying Module 600 According to Sixth Embodiment

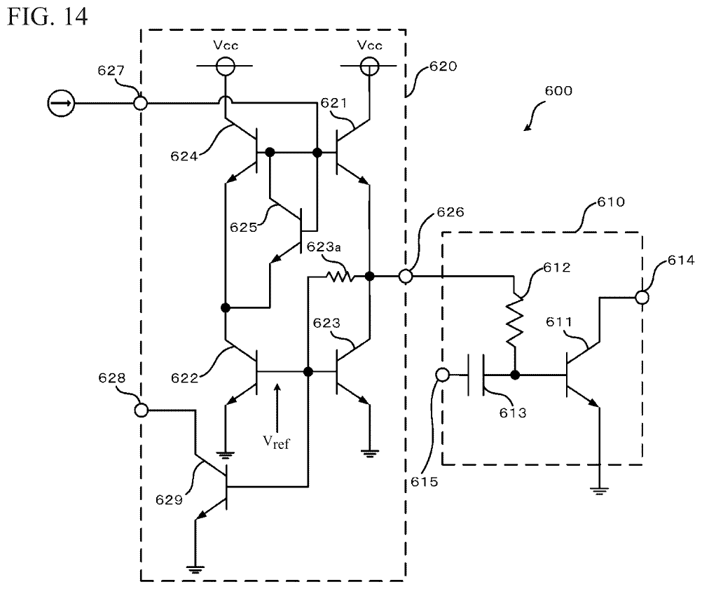

With reference to FIG. 14, the structure of a carrier bias circuit 620 of a power amplifying module 600 according to a sixth embodiment is described. FIG. 14 is a diagram depicting one example of the structure of the carrier bias circuit 620 in the power amplifying module 600 according to the sixth embodiment.

As depicted in FIG. 14, compared with the power amplifying module 500, the power amplifying module 600 further includes a transistor 629 in the carrier bias circuit 620. Also, in the power amplifying module 600, compared with the power amplifying module 500, the connection target of a detection terminal 628 is changed from the collector of the transistor 622 to the collector of the transistor 629. Components different from those of the power amplifying module 500 are described below.

The carrier bias circuit 620 includes a transistor 621, a transistor 622, a transistor 623, a resistor 623a, a transistor 624, a transistor 625, and the transistor 629.

The transistor 629 is configured of, for example, a bipolar transistor or a field-effect transistor. In the following, by way of example, description is made on the assumption that the transistor 629 is a bipolar transistor. Note that when the transistor 629 is a field-effect transistor, the base is read as the gate, the collector is read as the drain, and the emitter is read as the source in the following description.

The base of the transistor 629 is electrically connected to the base of the transistor 622 and the base of the transistor 623. The emitter of the transistor 629 is electrically connected to ground. Note that the collector of the transistor 629 is electrically connected to the detection terminal 628. That is, the transistor 629 is an inverting amplifier having its input terminal electrically connected to the input terminal of the inverting amplifier 122 of the power amplifying module 100 according to the first embodiment and inverting and amplifying a voltage supplied to its input terminal for output from its output terminal. With this, to the collector of the transistor 629, a current proportional to the current flowing through the collector of the transistor 622 can be let flow. Furthermore, with the transistor 622 and the transistor 629 arranged at an adjacent distance on the same semiconductor substrate, a current obtained by copying the current flowing through the collector of the transistor 622 can also be let flow through the collector of the transistor 629.

That is, a multiplying factor of the collector current of the transistor 629 with respect to the collector current of the transistor 622 can be freely selected based on the size ratio between the transistors 622 and 629. Specifically, when the transistor 622 and the transistor 629 are bipolar transistors, a multiplying factor of the collector current of the transistor 629 can be selected based on the emitter area ratio between the transistors 622 and 629. Also, when the transistor 622 and the transistor 629 are field-effect transistors, a multiplying factor of the drain current of the transistor 629 can be selected based on the gate width ratio between the transistors 622 and 629. With this, even if a circuit requiring a relatively large current is connected to the detection terminal 628, stable operation of the power amplifying module 600 can be made.

Also, for example, in the saturation detection circuit described in Patent Document 1 as a prior technical document, the input terminal of the saturation detector is electrically connected and thermally coupled to the base of the power amplifier to stabilize operation. However, in general, the temperature at the power amplifier greatly changes depending on the site where the power amplifier is arranged. Thus, in practice, it is difficult to arrange and thermally couple the saturation detector near a center portion of the power amplifier where the temperature most tends to become high.

By contrast, according to the structure of the carrier bias circuit 620 of the power amplifying module 600, it is possible to achieve stable operation without necessarily thermally coupling the transistor 629 connected to the detection terminal 628 and a transistor 611 configuring a carrier amplifier 610. With this, in the carrier bias circuit 620, compared with the saturation detection circuit described in the prior technical document, the transistors can be arranged relatively freely.

Note that in the carrier bias circuit 620, with the thermal environment of the transistor 629 brought close to the thermal environment of the transistor 622, operation can be further stabilized. Here, since the transistor 622 and the transistor 629 are sufficiently small compared with the transistor 611 configuring the carrier amplifier 610, the transistor 622 and the transistor 629 can be arranged at a short distance. Therefore, with the distance between the transistor 622 and the transistor 629 made shorter compared with the distance between the transistor 629 and the portion of the transistor 611 at the highest temperature (for example, a center portion of the transistor 611), the thermal environment of the transistor 629 can be brought close to the thermal environment of the transistor 622.

Note that the transistor 629 may be electrically connected to an inverting amplifier in any of the power amplifying module 100 according to the first embodiment to the power amplifying module 500 according to the fifth embodiment. Also in this case, an effect of allowing stable operation of each power amplifying module can be exerted.

### Power Amplifying Module 700 According to Seventh Embodiment

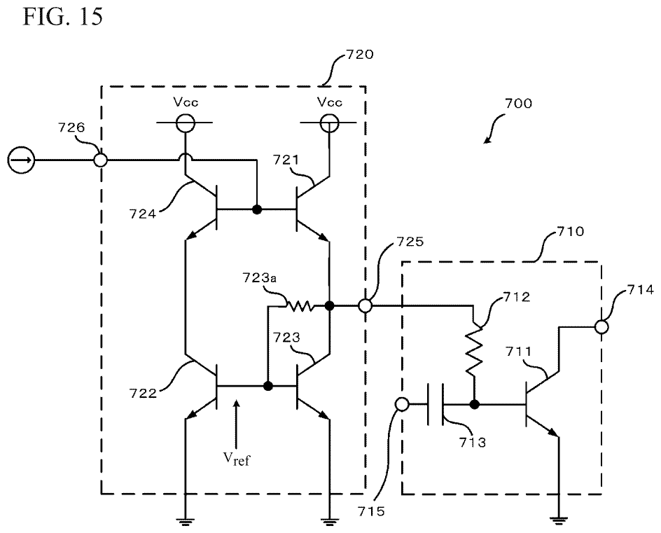

With reference to FIG. 15, the structure of a carrier bias circuit 720 of a power amplifying module 700 according to a seventh embodiment is described. FIG. 15 is a diagram depicting one example of the structure of the carrier bias circuit 720 of the power amplifying module 700 according to the seventh embodiment.

As depicted in FIG. 15, compared with the power amplifying module 400, the power amplifying module 700 has a structure in which the detection terminal 427 in the carrier bias circuit 420 is absent. That is, the carrier bias circuit 720 does not have a function of outputting the detection signal Dₛₐₜ. Furthermore, the power amplifying module 700 does not include the detection circuit 150 depicted in FIG. 1 and FIG. 3 to FIG. 6. The structure of the carrier bias circuit 720 is a structure in which the detection terminal 427 is removed from the carrier bias circuit 420, and description of each component of the carrier bias circuit 720 is therefore omitted.

The operation of the carrier bias circuit 720 is similar to the operation of the carrier bias circuit 320 and the carrier bias circuit 420, and the base current of a transistor 722 can be decreased. That is, in the carrier bias circuit 720, it is possible to suppress oscillation that can occur due to positive feedback of part of the emitter current of a transistor 721 as a base current of the transistor 722. Thus, in the carrier bias circuit 720 having the transistor 723, the circuit characteristics are stabilized.

### Power Amplifying Module 800 According to Eighth Embodiment

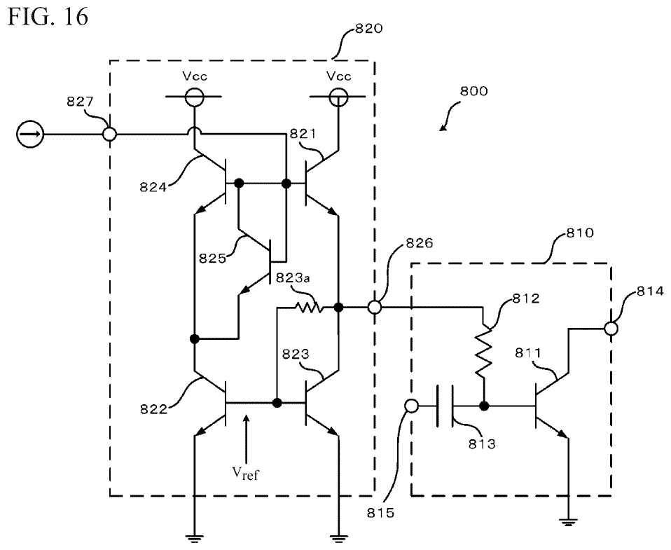

With reference to FIG. 16, the structure of a carrier bias circuit 820 of a power amplifying module 800 according to an eighth embodiment is described. FIG. 16 is a diagram depicting one example of the structure of the carrier bias circuit 820 of the power amplifying module 800 according to the eighth embodiment.

As depicted in FIG. 16, compared with the power amplifying module 500, the power amplifying module 800 has a structure in which the detection terminal 528 in the carrier bias circuit 520 is absent. That is, the carrier bias circuit 820 does not have a function of outputting the detection signal Dₛₐₜ. Furthermore, the power amplifying module 800 does not include the detection circuit 150 depicted in FIG. 1 and FIG. 3 to FIG. 6. The structure of the carrier bias circuit 820 is a structure in which the detection terminal 528 is removed from the structure of the carrier bias circuit 520, and description of each component of the carrier bias circuit 820 is therefore omitted.

The operation of the carrier bias circuit 820 is similar to the operation of the carrier bias circuit 520. To the collector of a transistor 824, a current proportional to the current inputted from a control terminal 827 can be let flow. Thus, in addition to the effects of the carrier bias circuit 720, an effect can be exerted in which the carrier bias circuit 820 can be configured with an input current with accuracy lower than the accuracy of the current inputted from a control terminal 726 in the carrier bias circuit 720.

### Power Amplifying Module 900 According to Ninth Embodiment

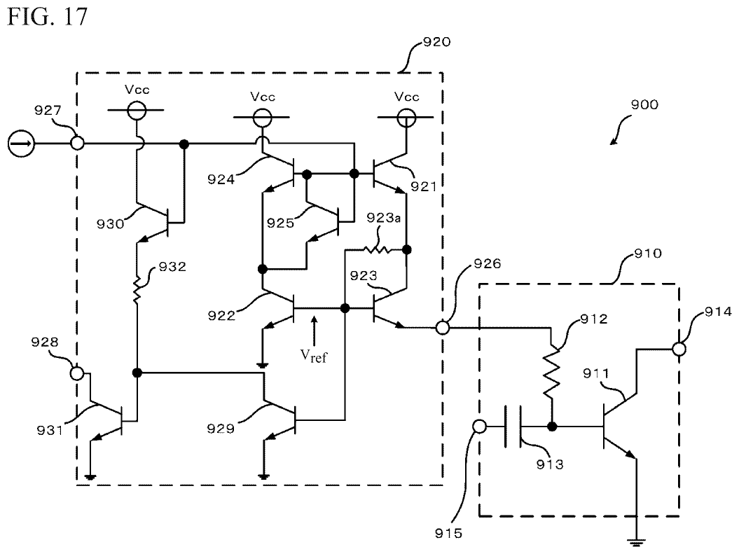

With reference to FIG. 17, the structure of a carrier bias circuit 920 of a power amplifying module 900 according to a ninth embodiment is described. FIG. 17 is a diagram depicting one example of the structure of the carrier bias circuit 920 of the power amplifying module 900 according to the ninth embodiment.

As depicted in FIG. 17, in the power amplifying module 900, compared with the power amplifying module 600, the carrier bias circuit 920 further includes transistors 930 and 931.

The transistor 930 and the transistor 931 are each configured of, for example, a bipolar transistor or a field-effect transistor. In the following, by way of example, description is made on the assumption that the transistor 930 and the transistor 931 are each a bipolar transistor. Note that when the transistor 930 and the transistor 931 are each a field-effect transistor, the base is read as the gate, the collector is read as the drain, and the emitter is read as the source in the following description.

The base of the transistor 930 is electrically connected to the base of a transistor 924 and the base of a transistor 925. The collector of the transistor 930 is electrically connected to the power supply Vcc. Note that the emitter of the transistor 930 is electrically connected via a resistor 932 to the base of the transistor 931.

Here, the emitter of the transistor 924 and the emitter of the transistor 925 are connected to the collector of a transistor 922. As with the transistor 222 of the power amplifying module 200, the collector potential of the transistor 922 increases as the bias current that the carrier bias circuit 920 supplies to a carrier amplifier 910 increases. Also, to the base of the transistor 924 and the base of the transistor 925, a signal obtained by shifting the voltage of a signal outputted from the collector of the transistor 922 by the voltage (V_{be}) between the base and the emitter of the transistor 925 is supplied. In other words, the potentials of the base of the transistor 924 and the base of the transistor 925 increase as the bias current that the carrier bias circuit 920 supplies to the carrier amplifier 910 increases.

In the power amplifying module 900, to the base of the transistor 924 and the base of the transistor 925, the base of the transistor 930 operating as a collector-ground amplifier is connected. With this, the voltage of a signal outputted from the emitter of the transistor 930 also increases as the bias current that the carrier bias circuit 920 supplies to the carrier amplifier 910 increases. Note that the signal outputted from the emitter of the transistor 930 is a signal branched in the course of a feedback circuit configured of the transistor 922 as an inverting amplifier and a transistor 921, and is a signal obtained by collector-ground amplification. Therefore, in the power amplifying module 900, the detection signal Dₛₐₜ with high accuracy outputted from the emitter of the transistor 930 can be obtained.

The base of the transistor 931 is electrically connected to the collector of a transistor 929. The collector of the transistor 931 is electrically connected to a detection terminal 928. Note that the emitter of the transistor 931 is electrically connected to ground.

Here, in the feedback circuit including the transistor 921 and the transistor 922, the base of the transistor 929 is connected to the base of the transistor 922 as an inverting amplifier. That is, since a signal inputted to the base of the transistor 929 is inputted without necessarily inversion and amplification at the transistor 922, the signal decreases as the bias current that the carrier bias circuit 920 supplies to the carrier amplifier 910 increases. Thus, the collector current of the transistor 929 decreases to decrease the voltage drop amount at the resistor 932. On the other hand, as described above, as the bias current that the carrier bias circuit 920 supplies to the carrier amplifier 910 increases, the emitter output of the transistor 930 increases. That is, a decrease of the voltage drop amount of the resistor 932 occurs with an increase of the emitter output of the transistor 930 and a decrease of the collector current of the transistor 929, thereby causing the base potential of the transistor 931 to greatly increase. As a result, when the bias current that the carrier bias circuit 920 supplies to the carrier amplifier 910 increases, the collector current of the transistor 931 can cause an output of the detection signal Dₛₐₜ that further greatly increases compared with the power amplifying module 600.

### Modification

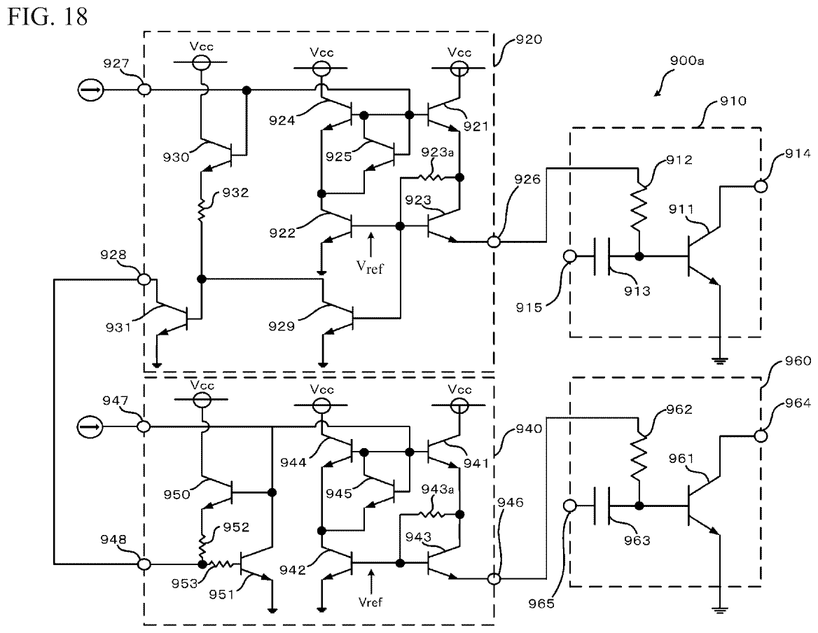

With reference to FIG. 18, a modification of the power amplifying module 900 is described. FIG. 18 is a diagram depicting one example of the structure of a peak bias circuit 940 in a power amplifying module 900a according to the modification. In the power amplifying module 900a according to the modification, as with the power amplifying module 500a, the detection signal Dₛₐₜ is directly inputted from the carrier bias circuit 920 to the peak bias circuit 940 to adjust the output of a peak amplifier 960. In the power amplifying module 900a, the peak bias circuit 940 controls a bias to be supplied to the peak amplifier 960, based on the detection signal Dₛₐₜ.

The peak bias circuit 940 includes a transistor 941, a transistor 942, a transistor 943, a resistor 943a, a transistor 944, a transistor 945, a transistor 950, a transistor 951, a resistor 952, a resistor 953, a control terminal 947, and an active control terminal 948. Since the structure of the peak bias circuit 940 is similar to the structure of the carrier bias circuit 920, components different from those of the carrier bias circuit 920 are described below. Note that the peak bias circuit 940 may have the same structure as that of the carrier bias circuit of each of the power amplifying modules according to the first embodiment, the second embodiment, the third embodiment, and the fifth embodiment.

The transistor 950 and the transistor 951 are each configured of, for example, a bipolar transistor or a field-effect transistor. In the following, by way of example, description is made on the assumption that the transistor 950 and the transistor 951 are each a bipolar transistor. Note that when the transistor 950 and the transistor 951 are each a field-effect transistor, the base is read as the gate, the collector is read as the drain, and the emitter is read as the source in the following description.

The base of the transistor 950 is electrically connected to the collector of the transistor 951 and is also electrically connected to the control terminal 947 to which a reference signal S_{base}, which is a signal for controlling a bias point of the peak amplifier 960, is inputted. Also, the base of the transistor 950 is electrically connected to the base of the transistor 941, the base of the transistor 944, and the base of the transistor 945. The collector of the transistor 950 is electrically connected to the power supply Vcc. The emitter of the transistor 950 is electrically connected to the base of the transistor 951 via the resistor 952 and the resister 953, and is also electrically connected via the resistor 952 to the active control terminal 948.

The base of the transistor 951 is electrically connected via the resistor 952 and the resistor 953 to the emitter of the transistor 950 and is also electrically connected via the resistor 953 to the active control terminal 948. The emitter of the transistor 951 is electrically connected to ground.

In a state in which the bias current that the carrier bias circuit 920 supplies to the carrier amplifier 910 is small, no current is outputted from the detection terminal 928. That is, the same amount of current flows through the emitter of the transistor 950, the resistor 952, the resistor 953, and the base of the transistor 951. In this case, the transistor 951 becomes in an ON state, and a large current flows through the collector of the transistor 951. Thus, the current left flow from the control terminal 947 is consumed by the collector of the transistor 951. Therefore, in a state in which the bias current that the carrier bias circuit 920 supplies to the carrier amplifier 910 is small, a circuit part configured of the transistor 941, the transistor 942, the transistor 943, the transistor 944, the transistor 945, and the resistor 943a becomes in an OFF state, and the bias current supplied from the peak bias circuit 940 to the peak amplifier 960 decreases.

On the other hand, in a state in which the bias current that the carrier bias circuit 920 supplies to the carrier amplifier 910 is large, the large detection signal Dₛₐₜ is supplied from the carrier bias circuit 920 to the active control terminal 948. With this, the current flowing through the resistor 952 increases, and thus the amount of a voltage drop occurring at the resistor 952 also increases. Then, the base voltage of the transistor 951 decreases to cause the transistor 951 to become in an OFF state. Therefore, no current flows through the collector of the transistor 951, and most of the control signal S_{base} inputted from the control terminal 947 is supplied to the circuit part configured of the transistor 941, the transistor 942, the transistor 943, the transistor 944, the transistor 945, and the resistor 943a. That is, the bias current that the peak bias circuit 940 supplies to the peak amplifier 960 increases.

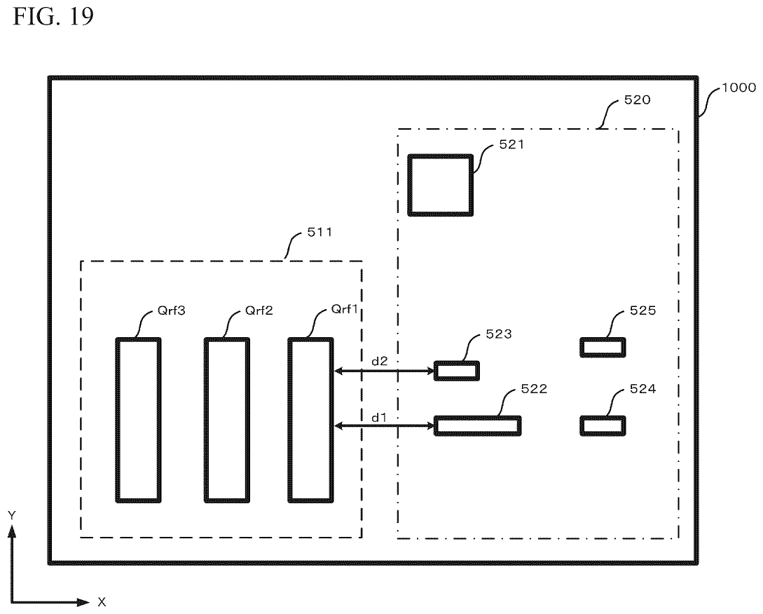

With reference to FIG. 19, a modification of the power amplifying module 500 according to the fifth embodiment is described. FIG. 19 is a plan view depicting a layout of the carrier bias circuit 520 on a semiconductor substrate 1000 in the power amplifying module 500a according to the modification of the fifth embodiment.

A transistor 511 included in a carrier amplifier 510 is configured of, for example, a plurality of transistors Qrf1, Qrf2, Qrf3, . . . connected in parallel. In FIG. 19, the plurality of transistors Qrf1, Qrf2, Qrf3, . . . each has a base electrode, a collector electrode, and an emitter electrode, and are provided so as to be aligned on the semiconductor substrate 1000 in an x direction.

On the semiconductor substrate 1000, a shortest distance d1 connecting the transistor 522 of the carrier bias circuit 520 and the transistor 511 included in the carrier amplifier 510 and a shortest distance d2 connecting the transistor 523 of the carrier bias circuit 520 and the transistor 511 included in the carrier amplifier 510 are short compared with a shortest distance connecting another transistor (here, any of the transistor 521, the transistor 524, and the transistor 525) included in the carrier bias circuit 520 and the transistor 511 included in the carrier amplifier 510. Here, the distance d1 is a shortest distance connecting the emitter electrode of a transistor closest to the transistor 522 (transistor Qrf1 in FIG. 19) among the plurality of transistors Qrf1, Qrf2, Qrf3, . . . and the emitter electrode of the transistor 522. Also, the distance d2 is a shortest distance connecting the emitter electrode of a transistor closest to the transistor 523 (transistor Qrf1 in FIG. 19) among the plurality of transistors Qrf1, Qrf2, Qrf3, . . . and the emitter electrode of the transistor 523. In FIG. 19, the distance d1 and the distance d2 are both short compared with a distance connecting between the emitter electrode of another transistor (for example, any of the transistor 521, the transistor 524, and the transistor 525) included in the carrier bias circuit 520 and the emitter electrode of a transistor closest to the other transistor among the plurality of transistors Qrf1, Qrf2, Qrf3, . . . .

With the above-described layout, among the plurality of transistors included in the carrier bias circuit 520, the transistor 522 and the transistor 523 are positioned closest to the transistor 511 of the carrier amplifier 510. Here, the temperature of the transistor 522 and the transistor 523 becomes on a par with the temperature of the transistor 511. Here, the base of each of the transistor 522 and the transistor 523 is commonly connected to the base of the transistor 511. Therefore, to the collector of each of the transistor 522 and the transistor 523, a current proportional to a current flowing through the collector of the transistor 511 flows. Here, the collector of the transistor 522 is determined by a current source and a sum of currents proportional to a current supplied from the current source. That is, when the current supplied from the current source is a current not dependent on the temperature, the base current of the transistor 511 having a base commonly connected to the base of the transistor 522 is constant. From the above, if difference in temperature occurs in the carrier bias circuit 520, that is, even if the temperature of the transistor 521, the transistor 524, and the transistor 525 fluctuates, the base current of the transistor 511 of the carrier amplifier 510 can be stabilized.

### Conclusion

The carrier bias circuit 120 of the power amplifying module 100 according to the exemplary embodiments of the present disclosure includes: the transistor 121 (first transistor) having an emitter or source from which a bias is supplied to the carrier amplifier 110 (first amplifier); the detection terminal 125 (first terminal) electrically connected to a circuit (for example, detection circuit 150) that controls a bias of a predetermined amplifier (for example, peak amplifier 130); and the inverting amplifier 122 (first inverting amplifier) having an input terminal electrically connected to the emitter or source of the transistor 121 (first transistor) and an output terminal electrically connected to a base or gate of the transistor 121 (first transistor) and the detection terminal 125 (first terminal), the inverting amplifier 122 (first inverting amplifier) inverting and amplifying a voltage supplied to the input terminal. That is, the inverting amplifier 122 outputs, from the output terminal, a signal in accordance with the bias supplied from the transistor 121 (first transistor) to the carrier amplifier 110 (first amplifier). With this, the carrier bias circuit 120 can supply a stable bias.

Also, the inverting amplifier 122 (first inverting amplifier) of the carrier bias circuit 120 of the power amplifying module 100 is an operational amplifier having an inverting input terminal electrically connected to the emitter or source of the transistor 121 (first transistor) and a non-inverting input terminal to which a reference signal (for example, reference voltage 126) for controlling the bias to the carrier amplifier 110 (first amplifier) is inputted. With this, a stable bias can be supplied in a simple structure.

Also, in the carrier bias circuit 220 of the power amplifying module 200, the transistor 222 (first inverting amplifier) is a transistor (for example, bipolar transistor or field-effect transistor), an output terminal is a collector or drain, and an input terminal is a base or gate. With this, the size can be decreased compared with the carrier bias circuit 120.

Also, in the carrier bias circuit 220 of the power amplifying module 200, the transistor 222 (first inverting amplifier) has the base or gate and the collector or drain electrically connected via a capacitor. With this, oscillation of the carrier bias circuit 220 due to noise can be suppressed.

Also, the carrier bias circuit 320 of the power amplifying module 300 further includes: the transistor 323 (second transistor) having a collector or drain and a base or gate electrically connected, the transistor 323 (second transistor) has the collector or drain electrically connected to an emitter or source of the transistor 321 (first transistor), the base or gate electrically connected to a base or gate of the transistor 322 (first inverting amplifier), and an emitter or source electrically connected to ground. With this, oscillation of the carrier bias circuit 320 due to noise can be suppressed.

Also, the carrier bias circuit 420 of the power amplifying module 400 further includes: the control terminal 426 (second terminal) to which the reference signal S_{base} for controlling the bias of the carrier amplifier 410 (first amplifier) is inputted; and the transistor 424 (third transistor) having a base or gate electrically connected to the control terminal 426 (second terminal) and a base or gate of the transistor 421 (first transistor) and an emitter or source electrically connected to a collector or drain of the transistor 422 (first inverting amplifier). With this, the output impedance of the carrier bias circuit 420 can be decreased.

Also, the carrier bias circuit 520 of the power amplifying module 500 further includes: the transistor 525 (fourth transistor) having a collector or drain and a base or gate electrically connected, and the transistor 525 (fourth transistor) has the collector or drain and the base or gate electrically connected to a base or gate of the transistor 524 (third transistor) and an emitter or source electrically connected to a collector or drain of the transistor 522 (first inverting amplifier). With this, the accuracy of current for determining the reference voltage V_{ref} can be decreased, and therefore the operation of the carrier bias circuit 520 can be stabilized.

Also, the carrier bias circuit 620 of the power amplifying module 600 further includes: the transistor 629 (second inverting amplifier) having an input terminal electrically connected to an input terminal (here, base or gate) of the transistor 622, the transistor 629 (second inverting amplifier) inverting and amplifying a voltage supplied to the input terminal for output from an output terminal. With this, a current proportional to the current flowing through a collector of the transistor 622 can be let flow through a collector of the transistor 629. Thus, even if a circuit requiring a relatively large current is connected to the detection terminal 628, stable operation of the power amplifying module 600 can be made.

Also, the transistor 629 (second inverting amplifier) of the power amplifying module 600 is a transistor having an emitter or source electrically connected to ground, an output terminal is a collector or drain, an input terminal is a base or gate, and the transistor 622 (first inverting amplifier) and the transistor 629 (second inverting amplifier) are provided on a same semiconductor substrate. With this, a current obtained by copying the current flowing through the collector of the transistor 622 can also be let flow through the collector of the transistor 629. Thus, even if a circuit requiring a relatively large current is connected to the detection terminal 628, stable operation of the power amplifying module 600 can be made.

Also, in the power amplifying module 600, a distance between the transistor 622 (first inverting amplifier) and the transistor 629 (second inverting amplifier) is short compared with a distance between the transistor 622 (first inverting amplifier) and the carrier amplifier 610 (first amplifier).

By bringing the thermal environment of the transistor 629 close to the thermal environment of the transistor 629, the operation can be further stabilized.

Also, in the carrier bias circuit 120 of the power amplifying module 100, the carrier amplifier 110 (first amplifier) is a carrier amplifier configuring a Doherty amplifier circuit, and the output terminal of the inverting amplifier 122 (first inverting amplifier) is electrically connected to the detection terminal 125 (first terminal) to which the peak bias circuit 140 (first bias circuit) that supplies a bias to the peak amplifier 130 (second amplifier), which configures the Doherty amplifier circuit, or the control circuit (first bias control circuit) that controls a bias supplied from the peak bias circuit 140 (first bias circuit) is electrically connected. With this, the carrier bias circuit 120 can cause the peak amplifier 130 to appropriately operate at a timing when the carrier amplifier 110 is saturated.

Also, in the carrier bias circuit 120 of the power amplifying module 100, the detection terminal 125 (first terminal) is connected to the peak bias circuit 140 (first bias circuit) and based on a detection signal outputted from the detection terminal 125, the peak bias circuit 140 supplies the bias to the peak amplifier 130 (second amplifier). With this, even without necessarily providing a detection circuit, it is possible to automatically operate the peak bias circuit 140 at an appropriate timing.

Also, in the power amplifying module 100, the peak bias circuit 140 (first bias circuit) is configured to include the transistor 141 (fifth transistor) having an emitter or source from which a bias is supplied to the peak amplifier 130 (second amplifier), and the detection signal is inputted to a base or gate of the transistor 141. With this, even without necessarily providing a detection circuit, it is possible to automatically operate the peak bias circuit 140 at an appropriate timing.

Also, in the power amplifying module 100, the peak bias circuit 140 (first bias circuit) further includes the transistor 142 (sixth transistor) having a base or gate connected to the emitter or source of the transistor 121 (first transistor), and the transistor 142 has a collector or drain connected to the base or gate of the transistor 141 (fifth transistor) and an emitter or source electrically connected to ground. With this, even when a voltage drop that cannot be sufficiently suppressed by the carrier bias circuit 120 occurs, the bias can be appropriately supplied to the peak amplifier 130.

Also, in the power amplifying module 500a, the amplifier 510 is a carrier amplifier configuring a Doherty amplifier circuit, and the base or gate of the transistor 524 (third transistor) and the collector or drain and the base or gate of the transistor 525 (fourth transistor) are electrically connected to the peak bias circuit 540 (first bias circuit) that supplies a bias to the peak amplifier 530 (second amplifier), which configures the Doherty amplifier circuit. With this, a detection signal with a more appropriate voltage can be inputted to the peak bias circuit 540.

Also, in the power amplifying module 500a, the peak bias circuit 540 (first bias circuit) includes: the transistor 541 (seventh transistor) having an emitter or source from which a bias is supplied to the peak amplifier 530 (second amplifier); the detection terminal 548 (second terminal) electrically connected to a circuit that controls a bias of a predetermined amplifier; and the transistor 542 (first inverting amplifier) having an input terminal electrically connected to the emitter or source of the transistor 541 and an output terminal electrically connected to a base or gate of the transistor 541 and the detection terminal 548, the transistor 542 (first inverting amplifier) inverting and amplifying a voltage supplied to the input terminal. With this, a stable bias can be supplied also in the peak bias circuit 540.

Also, in the carrier bias circuit 120 of the power amplifying module 100a, the peak amplifier (second amplifier) is configured to include the peak amplifier 130 (first peak amplifier) and the peak amplifier 130a (second peak amplifier) electrically connected in series to a preceding stage of the peak amplifier 130 (first peak amplifier), and the detection terminal 125 (first terminal) is electrically connected to the peak bias circuit 140a (second bias circuit) that supplies a bias to the peak amplifier 130a (second peak amplifier) or the control circuit (second bias control circuit) that controls a bias supplied from the peak bias circuit 140a (second bias circuit). With this, the carrier bias circuit 120 can cause the peak amplifier 130 to appropriately operate at a timing when the carrier amplifier 110 is saturated.

Also, in the carrier bias circuit 120 of the power amplifying module 100d, the detection terminal 125 (first terminal) is electrically connected to the drive-stage bias circuit 120c (bias circuit) that supplies a bias to the drive-stage amplifier 110d (second amplifier) electrically connected in series to the output-stage amplifier 110c (first amplifier) or the control circuit (bias control circuit) that controls a bias supplied from the drive-stage bias circuit 120c (bias circuit). With this, in accordance with the output level of the output-stage amplifier 110c, the output of the drive-stage amplifier 110d can be adjusted. Thus, distortion of the output of the output-stage amplifier 110c can be suppressed.

Also, the carrier bias circuit 720 of the power amplifying module 700 includes: the control terminal 726 to which the reference signal S_{base} for controlling a bias of a carrier amplifier 710 (first amplifier) is inputted; the transistor 721 (first transistor) having a base or gate electrically connected to the control terminal 726 and an emitter or source from which the bias is supplied to the carrier amplifier 710 (first amplifier); a transistor 723 (second transistor) having a collector or drain and a base or gate electrically connected and the collector or drain electrically connected to the emitter or source of the transistor 721 (first transistor); a transistor 724 (third transistor) having a base or gate electrically connected to the control terminal 726 and the base or gate of the transistor 721 (first transistor); and the transistor 722 (inverting amplifier) having a collector or drain electrically connected to an emitter or source of the transistor 724 (third transistor) and a base or gate electrically connected to the base or gate of the transistor 723 (second transistor), the transistor 722 (inverting amplifier) inverting and amplifying a voltage supplied to the base or gate. With this, the carrier bias circuit 720 can supply a stable bias. Also, it is possible to suppress oscillation that can occur due to positive feedback of part of the emitter current of the transistor 721 as a base current of the transistor 722.

Also, the carrier bias circuit 820 of the power amplifying module 800 further includes: a transistor 825 (fourth transistor) having a collector or drain and a base or gate electrically connected, and the transistor 825 (fourth transistor) has the collector or drain and the base or gate electrically connected to a base or gate of the transistor 824 (third transistor) and an emitter or source electrically connected to a collector or drain of a transistor 822 (inverting amplifier). With this, the accuracy of current for determining the reference voltage V_{ref} can be decreased, and therefore the operation of the carrier bias circuit 820 can be stabilized.

The above-described embodiments are for ease of understanding of the present disclosure and are not for limited interpretation of the present disclosure. The present disclosure can be changed or improved without necessarily deviating from the gist of the present disclosure, and the present disclosure also includes its equivalents. That is, those obtained by a person skilled in the art adding an appropriate design change to the embodiments are also included in the scope of the present disclosure as long as they have the features of the present disclosure. The elements included in the embodiments and their arrangements are not limited to those exemplary described but can be changed as appropriate.

### REFERENCE SIGNS LIST

100, 200, 300, 400, 500, 600, 700, 800, 900 power amplifying module
120, 220, 320, 420, 520, 620, 720, 820, 920 carrier bias circuit
121, 221, 321, 421, 521, 621, 721, 821, 921 transistor
122 inverting amplifier
222, 322, 422, 522, 622, 722, 822, 922 transistor

1. A bias circuit comprising:
a first transistor having an emitter or a source from which a bias is supplied to a first amplifier;
a first terminal electrically connected to a circuit that is configured to control a bias of a predetermined amplifier; and
a first inverting amplifier having a first input terminal electrically connected to the emitter or the source of the first transistor, and a first output terminal electrically connected to a base or a gate of the first transistor and to the first terminal,
wherein the first inverting amplifier is configured to invert and amplify a voltage at the first input terminal.

2. The bias circuit according to claim 1, wherein the first inverting amplifier is an operational amplifier having an inverting input terminal electrically connected to the emitter or the source of the first transistor and a non-inverting input terminal to which a reference signal for controlling the bias to the first amplifier is inputted.

3. The bias circuit according to claim 1, wherein the first inverting amplifier is a transistor, the first output terminal is a collector or a drain, and the first input terminal is a base or a gate.

4. The bias circuit according to claim 3, wherein the base or the gate of the first inverting amplifier is electrically connected to the collector or the drain via a capacitor.

5. The bias circuit according to claim 3, further comprising:
a second transistor having a collector or a drain and a base or a gate, the collector or the drain of the second transistor being electrically connected to the base or the gate of the second transistor,
wherein the collector or the drain of the second transistor is electrically connected to the emitter or the source of the first transistor,
wherein the base or the gate of the second transistor is electrically connected to the base or the gate of the first inverting amplifier, and
wherein an emitter or a source of the second transistor is electrically connected to ground.

6. The bias circuit according to claim 5, further comprising:
a second terminal to which a reference signal for controlling the bias of the first amplifier is inputted; and
a third transistor having a base or a gate electrically connected to the second terminal and to the base or the gate of the first transistor, and having an emitter or a source electrically connected to the collector or the drain of the first inverting amplifier.

7. The bias circuit according to claim 6, further comprising:
a fourth transistor having a collector or a drain and a base or a gate, the collector or the drain of the fourth transistor being electrically connected to the base or the gate of the fourth transistor,
wherein the collector or the drain of the fourth transistor is electrically connected to the base or the gate of the third transistor, the base or the gate of the fourth transistor is electrically connected to the base or the gate of the third transistor, and an emitter or a source of the fourth transistor is electrically connected to the collector or the drain of the first inverting amplifier.

8. The bias circuit according to claim 1, further comprising:
a second inverting amplifier having a second input terminal connected to the first input terminal of the first inverting amplifier, the second inverting amplifier being configured to invert and amplify a voltage at the second input terminal,
wherein the inverted and amplified voltage is output from a second output terminal.

9. The bias circuit according to claim 8,
wherein the second inverting amplifier is a transistor having an emitter or a source electrically connected to ground, the second output terminal is a collector or a drain, and the second input terminal is a base or a gate, and
wherein the first inverting amplifier and the second inverting amplifier are on a same semiconductor substrate.

10. The bias circuit according to claim 9, wherein a distance between the first inverting amplifier and the second inverting amplifier is shorter than a distance between the first inverting amplifier and the first amplifier.

11. The bias circuit according to claim 1,
wherein the first amplifier is a carrier amplifier of a Doherty amplifier circuit,
wherein an output terminal of the first inverting amplifier is electrically connected to the first terminal to which a first bias circuit or a first bias control circuit is electrically connected, and
wherein the first bias circuit is configured to supply a bias to a peak amplifier of the Doherty amplifier circuit, and the first bias control circuit is configured to control a bias supplied from the first bias circuit.

12. The bias circuit according to claim 11,
wherein the first terminal is connected to the first bias circuit, and
wherein the first bias circuit is configured to supply the bias to the peak amplifier based on a detection signal outputted from the first terminal.

13. The bias circuit according to claim 12,
wherein the first bias circuit comprises a fifth transistor having an emitter or a source from which a bias is supplied to the peak amplifier, and
wherein the detection signal is inputted to a base or gate of the fifth transistor.

14. The bias circuit according to claim 13,
wherein the first bias circuit further comprises a sixth transistor having a base or a gate connected to the emitter or the source of the first transistor, and
wherein the sixth transistor has a collector or a drain connected to the base or the gate of the fifth transistor, and an emitter or a source electrically connected to ground.

15. The bias circuit according to claim 7,
wherein the first amplifier is a carrier amplifier of a Doherty amplifier circuit,
wherein the base or the gate of the third transistor and the collector or the drain, and the base or the gate of the fourth transistor, are electrically connected to a first bias circuit, and
wherein the first bias circuit is configured to supply a bias to a peak amplifier of the Doherty amplifier circuit.

16. The bias circuit according to claim 15, wherein the first bias circuit comprises:
a seventh transistor having an emitter or a source from which a bias is supplied to the peak amplifier,
a second terminal electrically connected to a circuit that is configured to control a bias of a predetermined amplifier, and
an inverting amplifier having an input terminal electrically connected to the emitter or the source of the seventh transistor, and an output terminal electrically connected to a base or a gate of the seventh transistor and to the second terminal, the inverting amplifier being configured to invert and amplify a voltage at the input terminal.

17. The bias circuit according to claim 11,
wherein the peak amplifier comprises a first peak amplifier and a second peak amplifier that are electrically connected in series to a preceding stage of the first peak amplifier, and
wherein the first terminal is electrically connected to a second bias circuit or a second bias control circuit, the second bias circuit being configured to supply a bias to the second peak amplifier and the second bias control circuit configured to control a bias supplied from the second bias circuit.

18. The bias circuit according to claim 1, wherein the first terminal is electrically connected to a bias circuit or a bias control circuit, the bias circuit being configured to supply a bias to a second amplifier that is electrically connected in series to the first amplifier, and the bias control circuit being configured to control a bias supplied from the bias circuit.

19. A bias circuit comprising:
a control terminal to which a reference signal for controlling a bias of a first amplifier is inputted;
a first transistor having a base or a gate electrically connected to the control terminal, and an emitter or a source from which the bias is supplied to the first amplifier;
a second transistor having a collector or a drain and a base or a gate, the collector or the drain of the second transistor being electrically connected to the base or the gate of the second transistor, and the collector or the drain of the second transistor being electrically connected to the emitter or the source of the first transistor;
a third transistor having a base or gate electrically connected to the control terminal and to the base or the gate of the first transistor; and
an inverting amplifier having a collector or a drain electrically connected to an emitter or a source of the third transistor, and a base or a gate electrically connected to the base or the gate of the second transistor, the inverting amplifier being configured to invert and amplify a voltage at the base or the gate.

20. The bias circuit according to claim 19, further comprising:
a fourth transistor having a collector or a drain and a base or a gate that are electrically connected to each other,
wherein the collector or the drain of the fourth transistor and the base or the gate of the fourth transistor are electrically connected to the base or the gate of the third transistor, and an emitter or a source electrically connected to the collector or the drain of the inverting amplifier.
